(19) United States
(12) Patent Application Publication
(10) Pub. No.: US 2021/0057397 A1
(43) Pub. Date: Feb. 25, 2021

(54) ELECTRODELESS PASSIVE EMBEDDED SUBSTRATE

(71) Applicant: QUALCOMM Incorporated, San Diego, CA (US)

(72) Inventors: Kuiwon KANG, San Diego, CA (US); Seongryul CHOI, Seongnam (KR); Haekyun KIM, San Diego, CA (US)

(21) Appl. No.: 16/546,158

(22) Filed: Aug. 20, 2019

(51) Int. Cl. H01L 25/16; H01L 23/498; H01L 23/13; H01L 23/00; H01L 21/48

(52) U.S. Cl. CPC H01L 25/16; H01L 21/565; H01L 23/13; H01L 23/49816; H01L 24/16; H01L 24/32; H01L 24/73; H01L 21/4857; H01L 24/81; H01L 21/4853; H01L 24/83; H01L 24/92; H01L 23/49838; H01L 2924/19102; H01L 2924/19041; H01L 2224/16227; H01L 2224/32225; H01L 2224/73204; H01L 23/49822

(57) ABSTRACT

An electronic assembly is disclosed that includes an electrodeless passive component embedded in a cavity of a multilayer substrate, wherein the cavity has conductive elements formed on at least two sidewalls of the cavity. The conductive elements are configured to be electrically coupled to the electrodeless passive component. The electrodeless passive component may be located in a first metal layer adjacent an external surface of the multilayer substrate.

### FIELD OF DISCLOSURE

The present disclosure is related to electronic devices including packages with at least one die and multilayer substrate having an electrodeless passive component embedded within the substrate.

### BACKGROUND

Integrated circuit (IC) technology has achieved great strides in advancing computing power, signal processing and communications through miniaturization of active components. Integrated passive components have also been miniaturized, and the trend for further miniaturization of such components continues. Passive elements can comprise some of the larger elements in many integrated circuit devices and as such are often implemented off-chip as a surface mount device (SMD).

In particular, passive components in SMDs may be located on a substrate adjacent the die, or on a substrate on which the die is mounted. These passive components may be used for filtering and other circuits and may be located on the die side of the substrate as it is often desirable to locate the passive components as near the die as possible. The passive components may also be located on the bottom surface, i.e., “land side,” of the substrate for power supply filtering, noise suppression and other functionalities. In some instances the passive component may be located within the substrate to further minimize the distance to the die. However, this may lead to an increased thickness of the substrate to allow for the thickness of conventional passive components.

### SUMMARY

The following summary identifies various features and aspects of the disclosure and is not intended to be an exclusive or exhaustive description of the disclosed subject matter. Additional features and further details are found in the detailed description and appended claims. Inclusion in the Summary is not reflective of importance. Additional aspects will become apparent to persons skilled in the art upon reading the following detailed description and viewing the drawings that form a part thereof.

In one aspect, an electrodeless passive component is embedded in a cavity of the multilayer substrate of an electronic assembly. The electronic assembly includes a multilayer substrate having a plurality of metal layers in a dielectric. An electrodeless passive component is embedded in a cavity of the multilayer substrate. The cavity has conductive elements formed on at least two sidewalls of the cavity, and the conductive elements are configured to be electrically coupled to the electrodeless passive component.

In another aspect, a method of forming an electronic assembly includes forming a cavity in a multilayer substrate based on a cavity pattern. An electrodeless passive component is embedded in the cavity. Conductive elements are formed on at least two sidewalls of the cavity and are electrically coupled to the electrodeless passive component.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of embodiments of the present disclosure and are provided solely for illustration of the various aspects disclosed and not limitation thereof.

FIG. 1A is an illustration of an example conventional passive component.

FIG. 1B is an alternate view of the example conventional passive component.

FIG. 2 is an illustration of an electronic assembly according to one aspect of the present disclosure.

FIG. 3 is an illustration of an electronic assembly according to one aspect of the disclosure.

FIG. 4 is another illustration of an electronic assembly according to one aspect of the disclosure.

FIG. 5 shows one example functional schematic of devices that can include one or more devices in accordance with some examples of aspects of the disclosure.

FIG. 6A depicts a portion of an example process to form an electronic assembly according to one aspect of the disclosure.

FIG. 6B depicts a further portion of an example process to form an electronic assembly according to at least one aspect of the disclosure.

FIG. 6C depicts a further portion of an example process to form an electronic assembly according to one aspect of the disclosure.

FIG. 6D depicts a further portion of an example process to form an electronic assembly according to at least one aspect of the disclosure.

FIG. 6E depicts a further portion of an example process to form an electronic assembly according to at least one aspect of the disclosure.

FIG. 6F depicts a further portion of an example process to form an electronic assembly according to at least one aspect of the disclosure.

FIG. 6G depicts a further portion of an example process to form an electronic assembly according to at least one aspect of the disclosure.

FIG. 6H depicts a further portion of an example process to form an electronic assembly according to at least one aspect of the disclosure.

FIG. 6I depicts a further portion of an example process to form an electronic assembly according to at least one aspect of the disclosure.

FIG. 6J depicts a further portion of an example process to form an electronic assembly according to at least one aspect of the disclosure.

FIG. 6K depicts a further portion of an example process to form an electronic assembly according to at least one aspect of the disclosure.

FIG. 7 illustrates an exemplary method for forming an electronic assembly according to at least one aspect of the disclosure.

FIG. 8 illustrates an exemplary method for further forming an electronic assembly/package according to at least one aspect of the disclosure.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

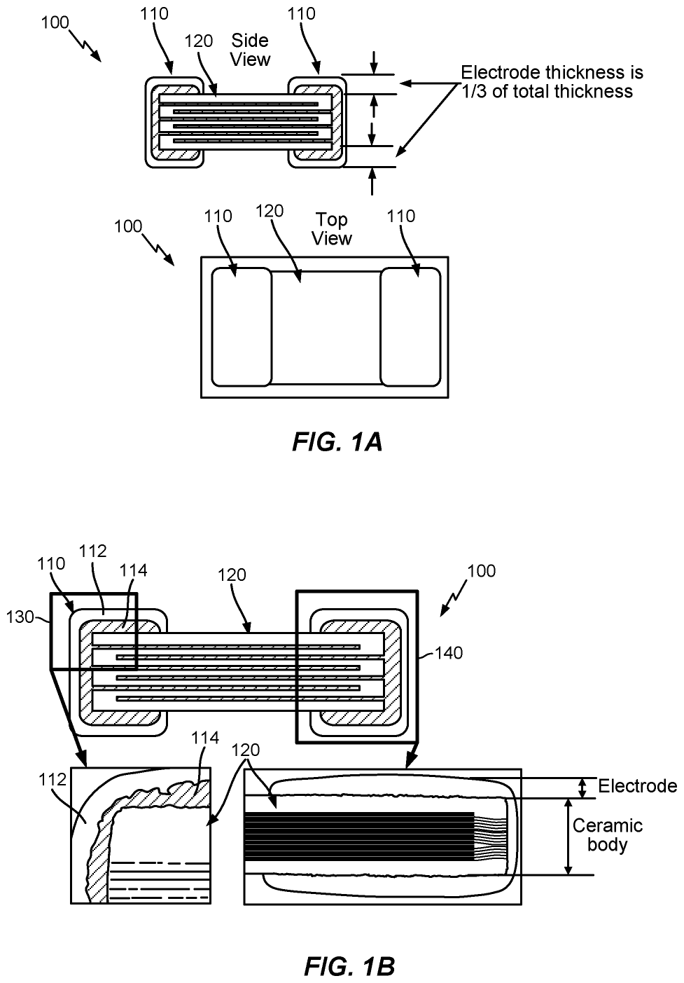

FIG. 1A is an illustration of an example conventional passive component 100. A side view/cross-sectional view of a schematic image of the passive component 100 is depicted (in this illustration a ceramic capacitor). The passive component 100 has two electrodes 110 and a body 120 (in this case a multi-layer ceramic capacitor) located between the electrodes 110. As illustrated, it can be seen that the electrodes 110 add significantly to the thickness of the passive component 100. The electrodes 110 add approximately one third of the total thickness of the passive component 100. Additionally, provided is a top view based on an actual image of passive component 100, which illustrates the two electrodes 110 and a body 120.

FIG. 1B is another illustration of the example passive component 100. A similar side view/cross-sectional view of a schematic image of the passive component 100 is provided with additional details of the electrode 110. As illustrated, the electrode 110 is formed having an inner layer 114 and an outer layer 112. The inner layer 114 may be formed by copper (Cu) paste dipping and then high temperature firing or other known techniques. The outer layer 112 may be formed from tin or nickel plating (e.g., for surface mount technology SMT/SMD) or copper for embedded components. A corner portion 130 of the passive component 100 is illustrated in a detailed cross-sectional view is provided based on an image showing an actual device having the outer layer 112 and inner layer 114 of electrode 110 formed about the body 120. Likewise, a larger portion 140 of the passive component 100 is illustrated in a detailed cross-sectional image showing an actual device having electrode 110 formed about the body 120 to provide some perspective of scale of the relative portions of passive component 100.

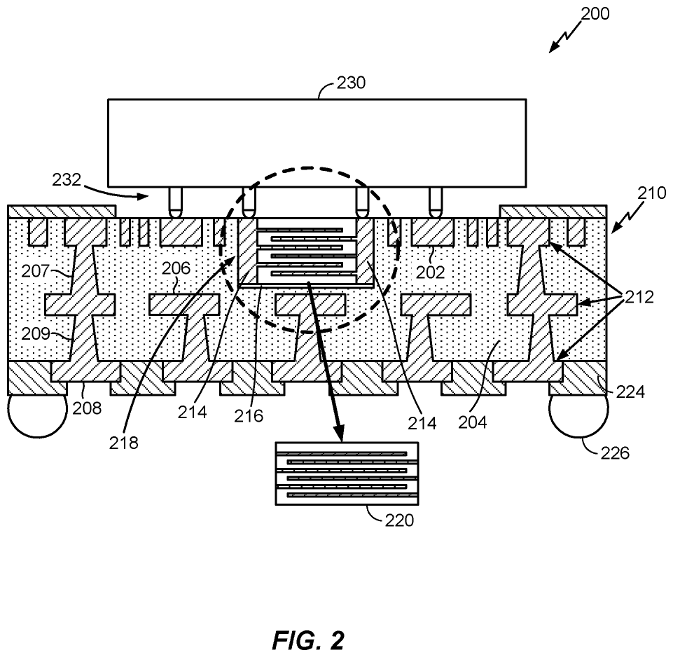

FIG. 2 is an illustration of an electronic assembly 200 according to one aspect of the present disclosure. As illustrated, the electronic assembly 200 includes a multilayer substrate 210 having a plurality of metal layers 212 and a dielectric 204 which may be formed of one or more layers of dielectric material. It will be understood that the multilayer substrate 210 may be a package substrate and may be part of a package including a protective body disposed about a die, allowing for its secure handling and installation. A package substrate may, for example, be configured to electrically interconnect a die to a wiring board and/or to distribute power. In another example, the multilayer substrate 210 may be an interposer, used as an electrical interface for connecting between disparate connection configurations. In some aspects, the multilayer substrate 210 has a core. In other aspects, the multilayer substrate 210 is a coreless substrate (e.g., a coreless embedded-trace-substrate (ETS)), which further reduces the thickness of the multilayer substrate 210 and available thickness for embedded components. An electrodeless passive component 220 may be embedded in a cavity 218 of the multilayer substrate 210. In an embodiment, the multilayer substrate 210 may include no active devices (e.g., transistors) within the layers of the multilayer substrate 210. For example, the electrodeless passive component 220 as illustrated is a multi-layer ceramic capacitor (MLCC). It will be appreciated that the various aspects disclosed herein can further be used with other types of passive components. As used herein, the term electrodeless passive component represents a passive component that is formed without electrodes for external connections, such as the MLCC illustrated and discussed above. The cavity 218 (defined by the elements it contains) has conductive elements 214 (e.g., metal or conductive paste) formed on at least two sidewalls of the cavity 218. The conductive elements 214 are electrically coupled to the electrodeless passive component 220. In this configuration, the electrodeless passive component 220 is located in a first metal layer of a plurality of metal layers of the multilayer substrate 210, which is adjacent an external surface of the multilayer substrate 210. Additionally, an adhesive 216 can be provided in the bottom of the cavity 218 to secure the electrodeless passive component 220. The adhesive thickness may be on the order of 5˜10 um. It will be appreciated that the illustrated configuration has the electrodeless passive component 220 located in a top metal layer (M1) adjacent the surface that is electrically coupled to die 230. In the illustrated configuration, the electrodeless passive component 220 is located directly underneath the die 230 to allow for a short connection length between the electrodeless passive component 220 and the die 230. Further, each of the conductive elements 214 are directly coupled to at least one die bump 232 of the die 230 to allow a direct electrical coupling to the electrodeless passive component 220. The die bumps 232 may be formed form copper, solder, other conductive materials and/or combinations thereof. Additionally, it will be appreciated that the cavity 218, electrodeless passive component 220, and conductive elements 214 could alternatively or in addition to, be located on a bottom metal layer adjacent the bottom surface (e.g., a land side) of the multilayer substrate 210.

The plurality of metal layers 212 may include a first metal layer 202, a second metal layer 206 and a third metal layer 208. Dielectric material may be used to form one or more dielectric layers, depicted as a common element and referred to herein as dielectric 204. In addition to the plurality of metal layers 212, conductive vias 207 may be formed through the dielectric 204 to allow for electrical coupling between the first metal layer 202 and the second metal layer 206. Conductive vias 209 may be formed through the dielectric 204 to allow for electrical coupling between the second metal layer 206 and the third metal layer 208. One or more electrodes 224 may be electrically coupled to the third metal layer 208 (in this configuration the bottom metal layer). The one or more electrodes 224 can serve as the coupling point to one or more external connection points 226. For example, the one or more electrodes 224 can serve as solder ball pads for the one or more external connection points 226, illustrated as solder balls. Combined vias 207 and 209 allow for the electrical coupling between the first metal layer 202 and third metal layer 208 and ultimately between the die 230 and the one or more external connection points 226. It will be appreciated that more or fewer metal layers may be included according to the various aspects disclosed herein. Further, the illustrations of the various metal layer patterns, vias, external connections, and like elements are merely for example and are not intended to limit the various aspects disclosed herein.

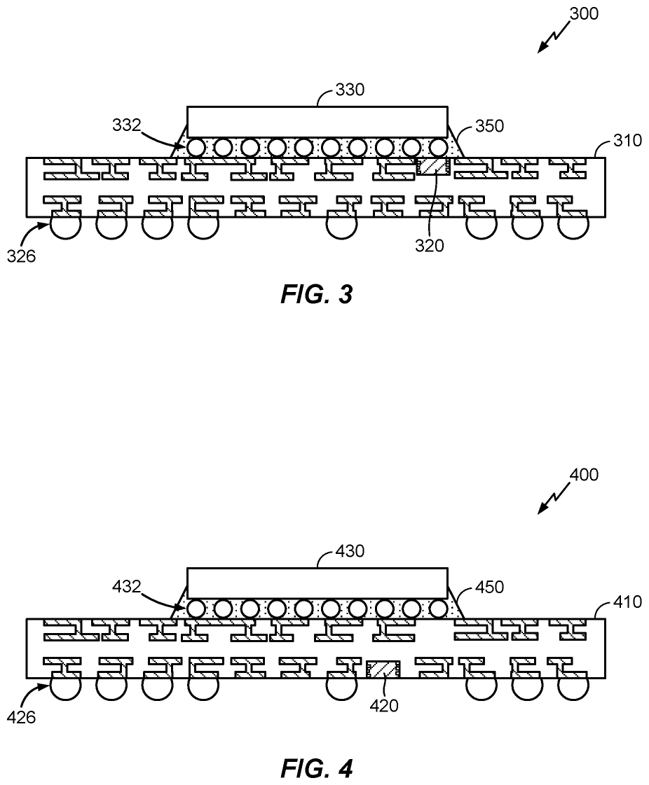

FIG. 3 is an illustration of an electronic assembly 300 according to one aspect of the present disclosure. As illustrated, the electronic assembly 300 is similar to the aspects illustrated in FIG. 2, so not all elements will be detailed to avoid redundancies. The electronic assembly 300 includes a multilayer substrate 310 (including, e.g., a package substrate, or interposer) having a plurality of metal layers. An electrodeless passive component 320 is embedded in a cavity of the multilayer substrate 310. The cavity has conductive elements formed on at least two sidewalls of the cavity. The conductive elements are electrically coupled to the electrodeless passive component 320. In this configuration, the electrodeless passive component 320 is also located in a top metal layer (M1) adjacent the surface that is electrically coupled to die 330. Further, the electrodeless passive component 320, as depicted, is located directly underneath the die 330 to allow for a short connection length between the electrodeless passive component 320 and the die 330. However, in this configuration, the electrodeless passive component 320 is located offset from the center of the die 330. Additionally, FIG. 3 depicts an underfill or mold compound 350 encapsulating at least a portion of the die 330 and a plurality of die bumps 332. The die bumps 332 are illustrated as solder balls, which may be part of a ball grid array (BGA), but may also land grid array (LGA) pads or copper, solder, other conductive materials and/or combinations thereof. Likewise, the external connection points 326 are illustrated as solder balls, which may be part of a ball grid array (BGA), but may also land grid array (LGA) pads or any other suitable connection type. The external connection points 326 are located on the land side/bottom of the multilayer substrate 310 to allow for external electrical connection and mounting of the electronic assembly 300.

FIG. 4 is another illustration of an electronic assembly 400 according to one aspect of the present disclosure. As illustrated, the electronic assembly 400 is similar to the aspects illustrated in FIG. 3, so not all elements will be detailed to avoid redundancies. The electronic assembly 400 includes a multilayer substrate 410 (including, e.g., a package substrate, or interposer) having a plurality of metal layers. A die 430 with underfill or mold compound 450 encapsulating at least a portion of die 430 and a plurality of die bumps 432. An electrodeless passive component 420 is embedded in a cavity of the multilayer substrate 410. In this configuration, the cavity and the electrodeless passive component 420 are also located in a bottom metal layer adjacent the bottom surface (e.g., a landside) of the multilayer substrate 410 and a plurality of external connection points 426 (illustrated as solder balls) being attached to the land side/bottom of the multilayer substrate 410 to allow for external electrical connection and mounting of the electronic assembly 400.

It will be appreciated from the foregoing illustrations that the location of the embedded electrodeless passive component is not limited to any specific position in the multilayer substrate. Additionally, although only one embedded electrodeless passive component is illustrated in the foregoing, it will be appreciated that in other aspects more than one electrodeless passive component may be embedded in a single multilayer substrate. Accordingly, it will be appreciated that the various illustrations provided herein are merely to provide examples for explaining the various aspects disclosed and are not to be construed to limit the disclosure.

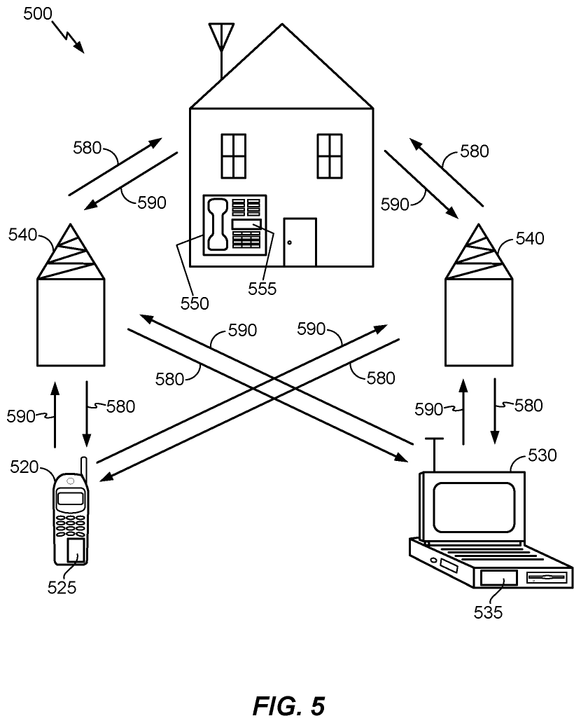

FIG. 5 illustrates an exemplary communication system 500 in which one or more aspects of the disclosure, e.g., as described in reference to any one or more of FIGS. 2-4. For purposes of illustration, FIG. 5 shows three remote units 520, 530, and 550 and two base stations 540. It will be recognized that conventional wireless communication systems may have many more remote units and base stations. The remote units 520, 530, and 550 include integrated circuits or other semiconductor devices 525, 535 and 555, respectively, having one or more electronic assemblies (e.g., 200, 300, 400) in accordance with one or more of the disclosed exemplary aspects as claimed or as described in reference to any one or more of FIGS. 2-4. FIG. 5 shows forward link signals 580 from the base stations 540 and the remote units 520, 530, and 550 and reverse link signals 590 from the remote units 520, 530, and 550 to the base stations 540.

In FIG. 5, the remote unit 520 is shown as a mobile telephone, the remote unit 530 is shown as a portable computer, and the remote unit 550 is shown as a fixed location remote unit in a wireless local loop system. These are only examples, both in terms of quantity and type. For example, the remote units 520, 530 and 550 may be one of, or any combination of a mobile phone, hand-held personal communication system (PCS) unit, portable data unit such as a personal data assistant (PDA), navigation device (such as GPS enabled devices), set top box, music player, video player, entertainment unit, fixed location data unit such as meter reading equipment, or any other device that stores or retrieves data or computer instructions, or any combination thereof. Although FIG. 5 illustrates remote units 520, 530 and 550 according to aspects of the disclosure, the disclosure is not limited to these exemplary illustrated units. Aspects of the disclosure may be suitably employed in any device having electronic assemblies as disclosed herein. Those skilled in the art will appreciate that aspects of the present disclosure may be incorporated into integrated devices, such as a mobile phone, which incorporate RF (Radio Frequency) communications in order to separate different frequency RF signal bands.

For example, the electronic assembly (e.g., 200, 300, 400) disclosed herein may be incorporated into a device that may include a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, or a device in an automotive vehicle. Further, it will be appreciated that aspects of the present disclosure may be used in a wide variety of devices and are not limited to the specific examples provided herein.

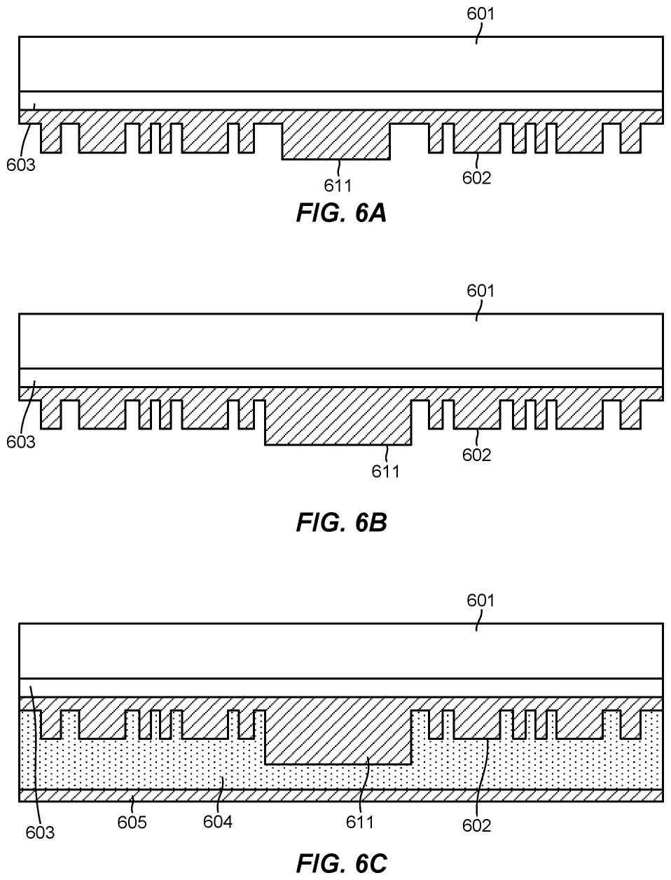

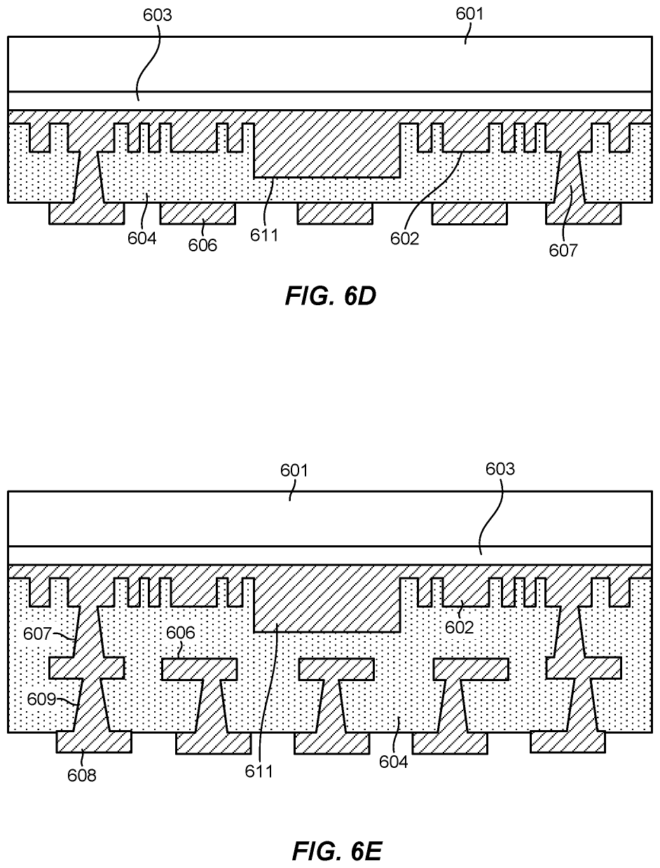

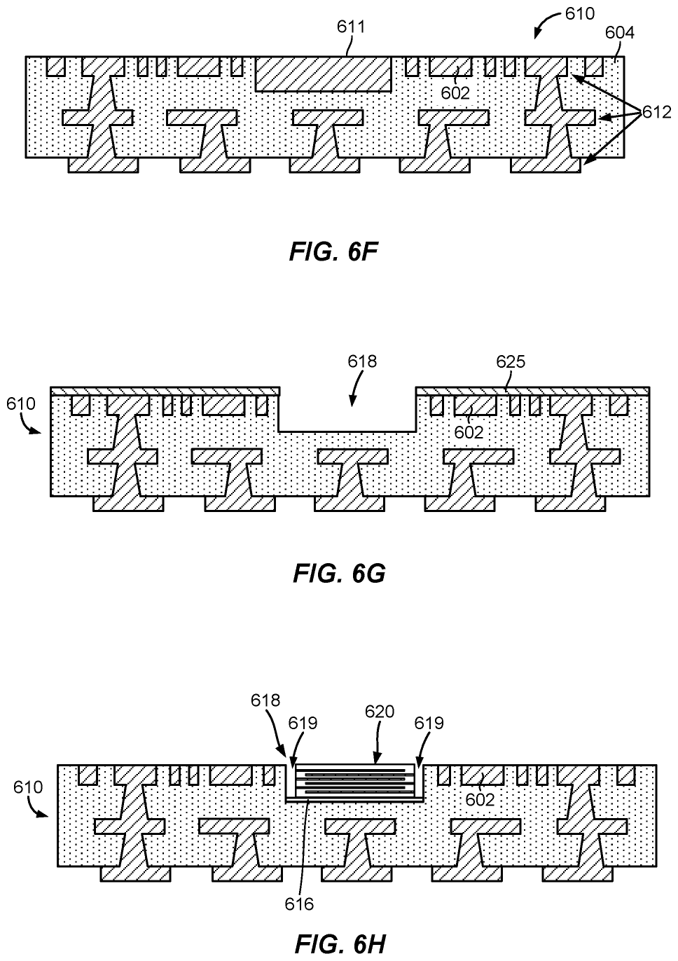

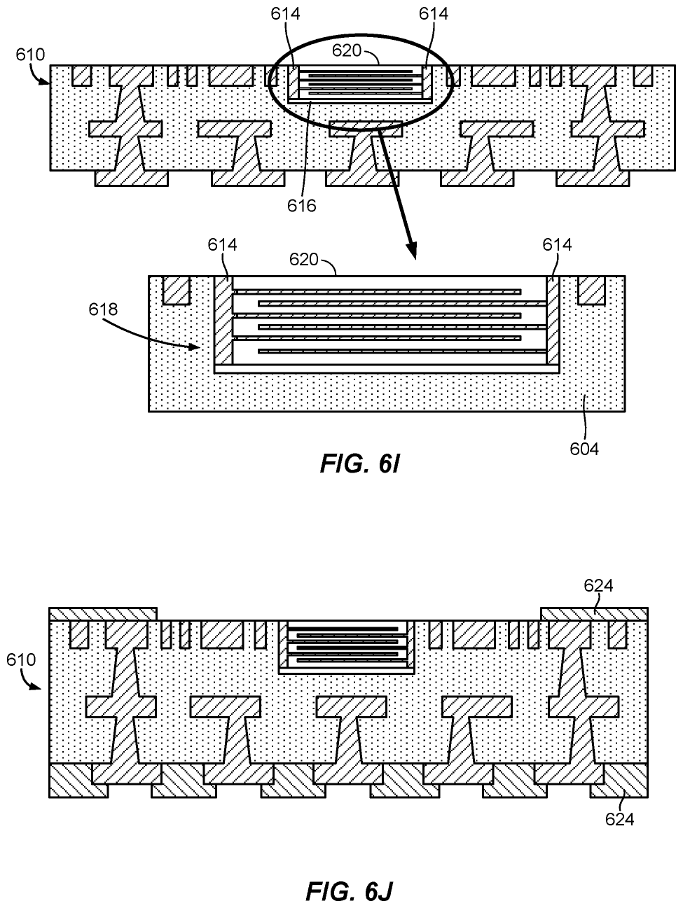

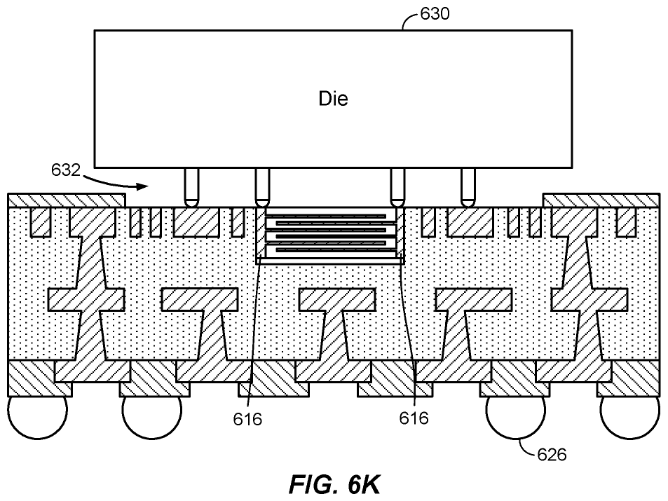

FIGS. 6A-6K illustrate an example process flow for forming an electronic assembly disclosed herein. Elements shown in FIGS. 6A-6K are simplified for conceptual purposes and are not intended to represent sizes, scale or numbers of elements as contemplated in the various aspects disclosed herein.

FIG. 6A depicts a carrier 601 having a carrier foil layer 603, which may be copper or other conductive material. A first metal layer 602 may be patterned for a the specific design being implemented. A portion of the first metal layer 602 may be used for forming a cavity pattern 611. It will be appreciated that the illustrations provided herein are solely to provide examples of basic fabrication techniques to explain the various aspects disclosed. It is not intended to be an exhaustive recitation of all process details and potential optional fabrication techniques and is not intended to limit the aspects disclosed herein to these illustrations. Further, not all elements introduced or illustrated in each FIG. will be detailed, to avoid unnecessary redundancy.

FIG. 6B depicts an additional plating process (e.g., one or more additional times) that further defines the cavity pattern 611. The additional plating process extends the cavity pattern 611 beyond the first metal layer 602 to a allow for a desired depth of the cavity to be formed. It will be appreciated that the dimensions of the cavity will be based on the dimensions of the electrodeless passive component that will be embedded in the cavity. It will be appreciated that the carrier 601 having the carrier foil layer 603 may still be attached to the first metal layer 602 to provide support during at least a portion of the fabrication process.

FIG. 6C depicts a dielectric 604 that is applied to the first metal layer 602 including the cavity pattern 611. For example, the dielectric material may be laminated to the first metal layer 602 including the cavity pattern 611. Further, a second metal foil layer 605 may be laminated on the dielectric 604. The second metal foil layer 605 may be copper or other conductive material. It will be appreciated that the carrier 601 having the carrier foil layer 603 may still be attached to the first metal layer 602 to provide support during at least this portion of the fabrication process.

FIG. 6D depicts the second metal foil layer 605 that may be patterned to form a second metal layer 606. Additionally, conductive vias 607 may be formed through the dielectric 604 to connect portions of the first metal layer 602 to portions of the second metal layer 606. It will be appreciated that the carrier 601 having the carrier foil layer 603 may still be attached to the first metal layer 602 to provide support during at least this portion of the fabrication process.

FIG. 6E depicts a further lamination process that may include additional dielectric material that overlays the second metal layer 606 and existing dielectric material to form dielectric 604, depicted as common element, since there are portions where there is no separation of the dielectric material and in some embodiments the material may be fused or bonded together. In addition to conductive vias 607 further conductive vias 609 may be formed through the dielectric 604 to connect portions of the second metal layer 606 to portions of a third metal layer 608, which may have been formed as discussed above in relation to the second metal layer 606. Conductive vias 607 allow for the electrical coupling of the first metal layer 602 (including cavity pattern 611) to the second metal layer 606 and conductive vias 609 allow for the electrical coupling of the second metal layer 606 to the third metal layer 608. Combined, conductive vias 607 and 609 allow for electrical coupling between the first metal layer 602 and third metal layer 608. It will be appreciated that more or fewer metal layers may be included according to the various aspects disclosed herein. Further, the illustrations of the various patterns and vias are merely for example and are not intended to limit the various aspects disclosed herein. Additionally, it will be appreciated that the carrier 601 having the carrier foil layer 603 may still be attached to the first metal layer 602 to provide support during at least this portion of the fabrication process.

FIG. 6F depicts the removal of the carrier 601 having the carrier foil layer 603 from the first metal layer 602. The first metal layer 602 may be further etched to remove excess metal to allow for the patterning to be completed. The multilayer substrate 610 remaining, after removal of the carrier 601 and the carrier foil layer 60, has a dielectric 604 (e.g., glass, prepreg (PPG), the like) which may be formed of one or more dielectric layers and a plurality of metal layers 612. As noted above, the multilayer substrate 610 may have a core or be coreless and in some aspects be a coreless embedded-trace-substrate (ETS). The multilayer substrate 610 may be patterned with post plating to form the various connection pads for coupling a die and external connections (e.g., solder balls, ball grid array (BGA), etc.). Additionally, it will be appreciated that the first metal layer 602 forms at least part of the cavity pattern 611, which may be further plated to obtain the desired dimensions of the cavity, as discussed above.

FIG. 6G depicts the multilayer substrate 610 which may have a mask 625 applied to allow etching of multilayer substrate 610 (e.g., the cavity pattern 611 discussed above) to form a cavity 618. The mask 625 provides protection of the top of the multilayer substrate 610 including the first metal layer 602 (also referred to herein as the top metal layer (M1). Additionally, it will be appreciated that other techniques of forming the cavity 618 may be used.

FIG. 6H depicts the multilayer substrate 610 having the electrodeless passive component 620 embedded in the cavity 618. In this illustration, the electrodeless passive component 620 is located at least in part in the first metal layer 602 portion of the multilayer substrate 610 adjacent an external surface (i.e., top/die side) of the multilayer substrate 610. It will be appreciated that the location of the cavity 618 and the electrodeless passive component 620 is not limited to the first metal layer 602 and can be located at any desired location in the multilayer substrate 610. As part of the embedding process, an adhesive 616 can be provided in the bottom of the cavity 618 to secure the electrodeless passive component 620 during further processing. Also, it will be noted that upon setting the electrodeless passive component 620 in the cavity 618 that gaps 619 are formed between at least two sidewalls of the cavity 618 and the electrodeless passive component 620.

FIG. 6I depicts the multilayer substrate 610 having the electrodeless passive component 620 embedded in the multilayer substrate 610, specifically the dielectric 604 (e.g., PPG) of the multilayer substrate 610. In this illustration, the electrodeless passive component 620, secured by adhesive 616, has conductive elements 614 formed on at least two sidewalls of the cavity 618. The conductive elements 614 can be formed by filling the gaps (e.g., where the gaps were in FIG. 6H) between the at least two sidewalls of the cavity and the electrodeless passive component 620 with a conductive material. For example, the gap may be filled by plating with copper (conductive material). Alternatively, the gap may be filled by a solder paste which is also the conductive material.

FIG. 6J depicts the addition of electrodes 624 to the multilayer substrate 610. Electrodes 624 that can be used (e.g., solder ball pads or other electrical contacts) to connect to external connection points (e.g. solder balls) on the land side of the multilayer substrate 610.

FIG. 6K depicts a die 630 that can be electrically coupled to a top side of the multilayer substrate 610, using conventional techniques. Additionally, a plurality of external connection points 626 can be electrically coupled to a land side/bottom of the multilayer substrate 610 that is opposite the die. In some aspects, the external connection points are solder balls. As noted above, the electrodeless passive component 620 can be located in any desired portion of the multilayer substrate 610. However, in some aspects disclosed herein, each of the conductive elements 614 is directly coupled to at least one die bump 632 of the die to allow a direct electrical coupling to the electrodeless passive component 620. This allows for a much shorter signal path between the die and the electrodeless passive component 620 than is achieved in conventional configurations with a passive SMD located on an external surface of multilayer substrate 610.

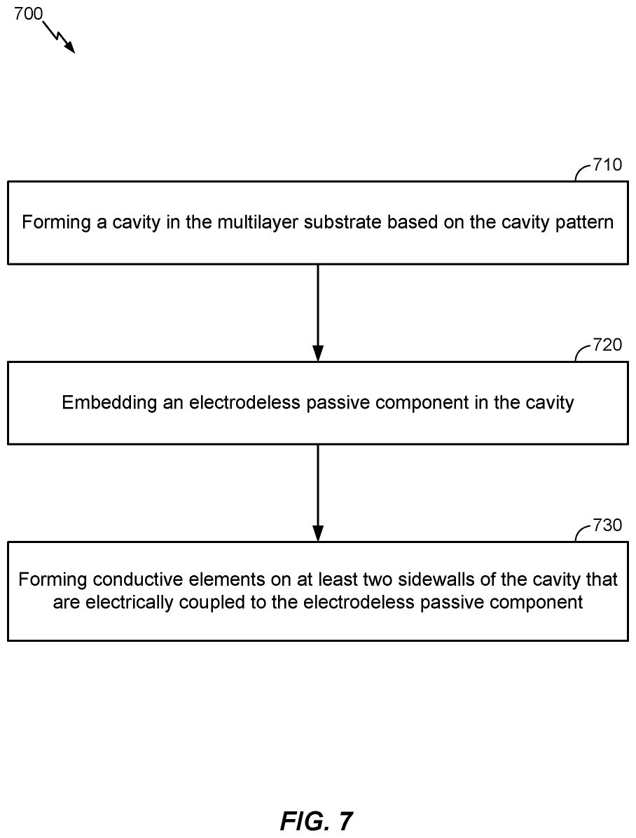

It will be appreciated that there are various methods for forming an electronic assembly which can include a multilayer substrate and may further include a die and suitable connectors for forming an electronic package, according to aspects disclosed herein. FIG. 7 is a flowchart illustrating an example method 700 in accordance with at least one aspect disclosed herein. For example, block 710 includes forming a cavity in a multilayer substrate based on a cavity pattern. For example, as discussed above, the multilayer substrate can be masked and the cavity pattern can be etched, thereby forming the cavity. As discussed above, the cavity pattern can be formed in part by one of the metal layers and then additional plating can be provided to achieve the desired dimensions for the cavity. Block 720 includes embedding the electrodeless passive component in the cavity. As noted above, the electrodeless passive component can be located at a first metal layer adjacent an external surface of the multilayer substrate, at a bottom metal layer or any other portion of the multilayer substrate. Block 730 includes forming conductive elements on at least two sidewalls of the cavity that are electrically coupled to the electrodeless passive component.

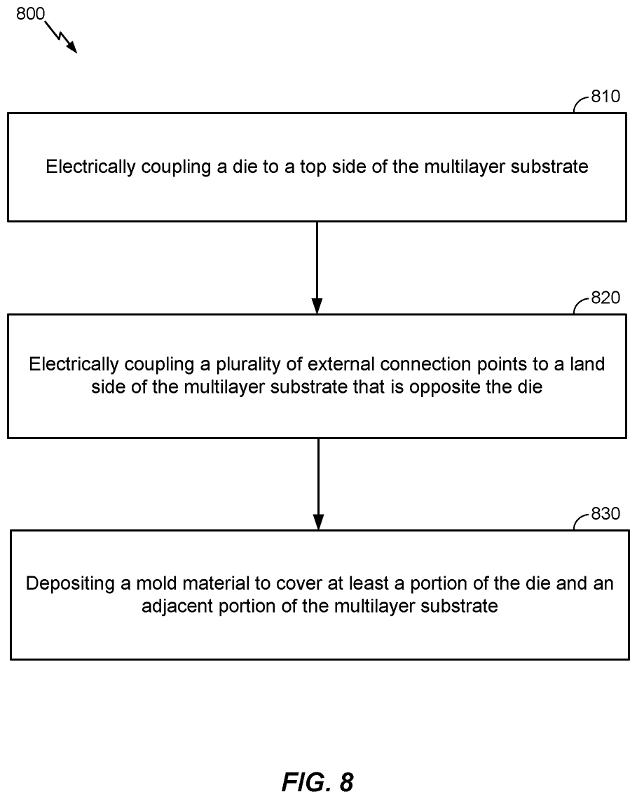

FIG. 8 is a flowchart further illustrating an example method 800 of further forming the electronic assembly. For example, block 810 includes electrically coupling a die to a top side of the multilayer substrate. Block 820 includes electrically coupling a plurality of external connection points to a land side of the multilayer substrate that is opposite the die. Block 830 includes depositing a mold material to cover at least a portion of the die and an adjacent portion of the multilayer substrate.

It will be appreciated from the foregoing disclosure that additional processes for fabricating the various aspects disclosed herein will be apparent to those skilled in the art and a literal rendition of the all variation of the processes discussed above and illustrated in the included drawings is not necessary.

The foregoing disclosed devices and functionalities, e.g., as described in reference to any one or more of FIGS. 2-6K may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor dies and packaged into a semiconductor chip. The chips are then may be employed in devices as described above.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, embodiments disclosed herein can include a non-transitory computer-readable media embodying a method for fabricating the various electronic assemblies as disclosed herein. Accordingly, the disclosure is not limited to illustrated examples as any means for performing the functionality described herein are contemplated by the present disclosure.

While the foregoing disclosure shows various illustrative embodiments, it should be noted that various changes and modifications could be made herein without departing from the scope of the teachings of the present disclosure as defined by the appended claims. The various materials identified for example and illustration may be substituted by known equivalent or alternative materials. The example fabrication process discussed above may have various process operations combined or split into additional process operations. Additionally, the functions, steps and/or actions described in the method claims in accordance with the embodiments of the disclosure described herein need not be performed in any particular order. Furthermore, although elements of the present disclosure may be described or claimed in the singular, the plural is contemplated unless limitation to the singular is explicitly stated.

1. An electronic assembly comprising:
a multilayer substrate having a plurality of metal layers in a dielectric; and
an electrodeless passive component embedded in a cavity of the multilayer substrate, wherein the cavity has conductive elements formed on at least two sidewalls of the cavity, and wherein the conductive elements are configured to be electrically coupled to the electrodeless passive component.

2. The electronic assembly of claim 1, wherein the electrodeless passive component is located in a first metal layer adjacent an external surface of the multilayer substrate.

3. The electronic assembly of claim 2, wherein the external surface is configured to couple to a die and the first metal layer is a top metal layer of the multilayer substrate.

4. The electronic assembly of claim 2, wherein the external surface is on a land side and the first metal layer is a bottom metal layer.

5. The electronic assembly of claim 2, further comprising:
a die electrically coupled to the external surface of the multilayer substrate.

6. The electronic assembly of claim 5, wherein the electrodeless passive component is located directly underneath the die.

7. The electronic assembly of claim 6, wherein each of the conductive elements are directly coupled to at least one die bump of a plurality of die bumps of the die to allow a direct electrical coupling to the electrodeless passive component.

8. The electronic assembly of claim 7, further comprising an underfill encapsulating at least a portion of the die and the plurality of die bumps.

9. The electronic assembly of claim 5, further comprising:
a plurality of external connection points electrically coupled to a land side of the multilayer substrate that is opposite the die.

10. The electronic assembly of claim 9, wherein the plurality of external connection points are solder balls.

11. The electronic assembly of claim 1, further comprising:
an adhesive positioned in a bottom of the cavity to adhere the electrodeless passive component in the cavity.

12. The electronic assembly of claim 1, wherein the multilayer substrate is a coreless embedded-trace-substrate (ETS).

13. The electronic assembly of claim 1, wherein the electrodeless passive component is a multi-layer ceramic capacitor (MLCC).

14. The electronic assembly of claim 1, wherein the electronic assembly is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a component in an automotive vehicle.

15. A method of forming an electronic assembly, comprising:
forming a cavity in a multilayer substrate based on a cavity pattern;
embedding an electrodeless passive component in the cavity; and
forming conductive elements on at least two sidewalls of the cavity that are electrically coupled to the electrodeless passive component.

16. The method of claim 15, wherein forming the cavity comprises:
masking the multilayer substrate; and
etching the cavity pattern to form the cavity.

17. The method of claim 15, wherein forming the cavity pattern comprises:
forming a portion of the cavity pattern in a first metal layer; and
performing one or more plating operations on the portion to form the cavity pattern.

18. The method of claim 15, wherein forming the conductive elements comprises:
filling gaps between the at least two sidewalls of the cavity and the electrodeless passive component with a conductive material.

19. The method of claim 18, wherein the gaps are filled by plating and the conductive material is copper.

20. The method of claim 18, wherein the gaps are filled by a solder paste.

21. The method of claim 15, further comprising:
electrically coupling a die to a top side of the multilayer substrate, wherein the electrodeless passive component is located in a first metal layer adjacent an external surface of the multilayer substrate.

22. The method of claim 21, further comprising:
electrically coupling a plurality of external connection points to a land side of the multilayer substrate that is on an opposite side of the multilayer substrate from the die.

23. The method of claim 22, wherein the plurality of external connection points are solder balls.

24. The method of claim 22, wherein the external surface is on the land side and the first metal layer is a bottom metal layer.

25. The method of claim 21, wherein the external surface is adjacent the die and the first metal layer is a top metal layer of the multilayer substrate.

26. The method of claim 21, wherein the electrodeless passive component is located directly underneath the die.

27. The method of claim 26, wherein each of the conductive elements is directly coupled to at least one bump of the die to allow a direct electrical coupling to the electrodeless passive component.

28. The method of claim 15, wherein the electrodeless passive component is a multi-layer ceramic capacitor (MLCC).

29. The method of claim 15, wherein the multilayer substrate is a coreless embedded-trace-substrate (ETS).

30. The method of claim 15, further comprising:
providing an adhesive in a bottom of the cavity to adhere the electrodeless passive component in the cavity.
